(19) United States
(12) Patent Application Publication
(10) Pub. No.: US 2001/0017380 A1
(43) Pub. Date: Aug. 30, 2001

(54) Semiconductor integrated circuit

(75) Inventors: Hitoshi Ikeda, Kawasaki (JP); Shinya Fujioka, Kawasaki (JP)

Correspondence Address: ARENT FOX KINTNER PLOTKIN & KAHN, PLLC, Suite 600, 1050 Connecticut Avenue, N.W., Washington, DC, 20036-5339, US

(73) Assignee: FUJITSU LIMITED

(21) Appl. No.: 09/773,012

(22) Filed: Jan. 31, 2001

(30) Foreign Application Priority Data
Feb. 28, 2000 (JP) 2000-051049

(51) Int. Cl. H01L 31/0336

(52) U.S. Cl. 257/200

(57) ABSTRACT

Memory cell blocks respectively have a plurality of memory cell rows and a redundancy memory cell row for relieving a defect in these memory cell rows, memory cells being arranged in the memory cell rows. A first decoder selects any of the memory cell blocks. A second decoder selects any of the memory cell rows in the memory cell block. The operation of the second decoder not in use for decoding in the redundancy memory cell row is suspended when the redundancy memory cell row operates. The absence of unnecessary circuit operation allows a reduction in power consumption when the redundancy memory cell row operates. Even in a semiconductor integrated circuit having a plurality of memory banks each including the plurality of memory cell blocks, the first decoder, and the second decoder, it is possible to reduce power consumption when the redundancy memory cell rows operates.

### BACKGROUND OF THE INVENTION

1. Field of the Invention

The present invention relates to a semiconductor integrated circuit having memory cells, and more particularly to a semiconductor integrated circuit having redundancy circuits for relieving defects.

2. Description of the Related Art

In general, semiconductor integrated circuits such as a DRAM have redundancy circuits in order that defects resulting from lattice defects in the substrates, particles in the fabrication processes, and the like are relieved for improved yields.

FIG. 1 shows a configuration example of a memory core unit 2 in a DRAM having redundancy circuits of this type.

The memory core unit 2 has a memory cell array 6 in which memory cell blocks 4 are arranged vertically and horizontally. Each of the memory cell blocks 4 includes a plurality of memory cells (not shown) arranged vertically and horizontally. A word line decoder row 8 and a column line decoder row 10 are arranged on the periphery of the memory cell array 6, along the verti cal and horizontal directions of the diagram, respectively.

FIG. 2 shows a memory cell block 4 and its peripheral circuits.

The word line decoder row 8 comprises a plurality of word line decoders 8a and a redundancy word line decoder 8b. word lines WL and a redundancy word line RWL are extended from the word line decoders 8a and 8b toward the memory cell blocks 4 that are arranged along the horizontal direction of the diagram. The column line decoder row 10 comprises a plurality of column line decoders 10a and a redundancy column line decoder 10b. Column lines CL and a redundancy column line RCL are extended from the column line decoders 10a and 10b toward the memory cell blocks 4 that are arranged along the vertical direction of the diagram. Although omitted from the diagram, bit lines are formed inside the memory cell block 4, along the column lines CL and the redundancy column line RCL. The bit lines are connected to a plurality of memory cells MC arranged along the vertical direction of the diagram. Here, groups of memory cells MC arranged along the vertical and horizontal directions of the diagram will be referred to as memory cell rows. A memory cell row 14a (the black-dotted area along the horizontal direction of the diagram) connected to the redundancy word line RWL consists of redundancy memory cells MC for relieving the word lines WL. A memory cell row 14b (the black-dotted area along the vertical direction of the diagram) connected to the redundancy column line RCL through the bit lines (not shown) consists of redundancy memory cells MC for relieving the column lines CL (or the bit lines). Besides, sense amplifier rows 12 having a plurality of sense amplifiers are arranged in between the memory cell block 4 and the column line decoder row 10 and in between the memory cell blocks 4 arranged along the vertical direction of the diagram.

In the DRAM described above, i-f, for example, the memory cell MC marked with “x” in the memory cell block 4 is defective, then not the column line decoder 10a corresponding to that memory cell MC but the redundancy column line decoder 10b is put into operation. Then, as a substitute for the memory cell row containing the defective memory cell MC, the memory cell row 14b connected to the redundancy column line RCL is used to relieve the defect. Alternatively, the word line decoder 8a corresponding to the defective memory cell MC is kept out of operation, and the redundancy word line decoder 8b is operated instead. Then, as a substitute for the memory cell row containing the defective memory cell MC, the memory cell row 14a connected to the redundancy word line RWL is used to relieve the defect. Such a relief is provided not only for defective memory cells MC but also for other defects inside the memory core unit 2, including word line defects, column line defects, and bit line defects.

FIG. 3 shows address decoders and redundancy circuits for selecting the column line decoders 10a and 10b, i.e., column-address-related circuitry.

A predecoder 16 receives an upper bit signal out of a column address signal CADDZ, and outputs the decoded signal as a decoding signal CAAnZ. A predecoder 18 receives a lower bit signal out of the column address signal CADDZ, and outputs the decoded signal as a decoding signal CABmZ. Thus, an address signal is decoded in two stages by the predecoders 16, 18 and the column line decoders 10a. The decoding signals CMnZ and CABmZ are supplied to the plurality of column line decoders 10a.

A plurality of redundancy address decision circuits 20 each receive the column address signal CADDZ and output a redundancy signal CRDNZ. The redundancy address decision circuits 20 have fuses, for example. Then, in a testing process, the fuses corresponding to defective addresses are blown beforehand on the basis of the test results. The redundancy address decision circuits 20 activate (turn to high level) the redundancy signal CRDNZ when the fuse information and the column address signal CADDZ coincide with each other.

When the redundancy signal CRDNZ is activated, a redundancy decision circuit 22 turns a timing signal RCLPZ to high level in synchronization with a timing signal TCLPZ, and maintains a timing signal CLPZ at low level. When the redundancy signal CRDNZ is inactivated, the redundancy decision circuit 22 turns the timing signal CLPZ to high level in synchronization with the timing signal TCLPZ and maintains the timing signal RCLPZ at low level.

The column line decoders 10a decode the decoding signals CAAnZ and CABmZ from the predecoders 16 and 18 in synchronization with the timing signal CLPZ, and output the decoded signals to the column lines CL. The column line decoders 10a turn their column lines CL to high level upon receiving predetermined decoding signals CMnZ and CABmz along with the timing signal CLPZ of high level. Incidentally, the column line decoders 10a shown in broken lines are decoders in adjacent memory cell blocks 4.

The redundancy column line decoder 10b decodes the decoding signal CAAnZ from the predecoder 16 in synchronization with the timing signal RCLPZ, and outputs the decoded signal to the redundancy column line RCL. The column line decoder 10b turns the column line RCL to high level upon receiving a predetermined decoding signal CAAnZ and the timing signal RCLPZ of high level.

As described above, the predecoder 16 receives the upper address signal and selects any of the memory cell blocks 4 or the redundancy column line decoder 10b. The predecoder 18 receives the lower address signal and selects a column line decoder 10a within the memory cell block 4 selected.

FIG. 4 shows the operation of the circuits shown in FIG. 3.

In the operating cycle C1, the predecoders 16 and 18 decode the column address signal CADDZ, and output the decoded signals as the decoding signals CAAnZ and CABmZ, respectively (FIG. 4(a)). The timing signal TCLPZ is turned to high level for a predetermined period. The column address signal CADDZ supplied at the operating cycle C1 is not an address corresponding to a defective memory cell MC. Therefore, the redundancy address decision circuits 20 maintain the redundancy signal CRDNZ inactivated (FIG. 4(b)).

The redundancy decision circuit 22 receives the redundancy signal CRDNZ of low level, and activates (turns to high level) the timing signal CLPZ in synchronization with the timing signal TCLPZ (FIG. 4(c)). The redundancy decision circuit 22 maintains the timing signal RCLPZ inactivated (at low level) (FIG. 4(d)).

The column line decoders 10a individually decode the decoding signals CAAnZ and CABmZ in synchronization with the timing signal CLPZ, and turn a predetermined column line CL to high level (FIG. 4(e)). The column line decoder 10b is inactivated under the low level of the timing signal RCLPZ. That is, the redundancy column line RCL maintains its low level (FIG. 4(f)). Then, a memory cell row corresponding to the predetermined column line CL is selected for a read or write operation.

Next, in the operating cycle C2, the predecoders 16 and 18 decode the column address signal CADDZ and output the decoded signals as the decoding signals CAAnZ and CABmZ, respectively. The timing signal TCLPZ is turned to high level for a predetermined period. The column address signal CADDZ supplied at the operating cycle C2 is an address corresponding to a defective memory cell MC. The redundancy address decision circuits 20 receive this defective address (column address signal CADDZ) and activate (turn to high level) the redundancy signal CRDNZ (FIG. 4(g)).

The redundancy decision circuit 22 receives the redundancy signal CRDNZ of high level, and activates (turns to high level) the timing signal RCLPZ in synchronization with the timing signal TCLPZ (FIG. 4(h)). The redundancy decision circuit 22 maintains the timing signal CLPZ inactivated (at low level) (FIG. 4(i)).

The column line decoders 10a are inactivated under the low level of the timing signal CLPZ. That is, the column lines CL maintain their low level (FIG. 4(j)). The column line decoders 10b decode the decoding signal CAAnZ in synchronization with the timing signal RCLPZ, and turn a predetermined redundancy column line RCL to high level (FIG. 4(k)). Then, a redundancy memory cell row 14b (FIG. 2) corresponding to this redundancy column line RCL is selected for a read or write operation.

Incidentally, FIGS. 2 through 4 have dealt with the case of selecting a column line CL or a redundancy column line RCL, whereas the word lines WL and the redundancy word lines RWL are also selected by using similar circuits under similar timing.

By the way, the predecoders 16 and 18 shown in FIG. 3 make an operation whenever they receive a change in the column address signal CADDZ. Meanwhile, the column line decoders 10a are inactivated by the timing signal CLPZ if the column address signal CADDZ is a defective address. The column line decoders 10a therefore make no use of the decoding signal CABmZ output from the predecoder 18. In other words, there has been a problem that when the redundancy circuits are in operation, the predecoder 18 in no need of operation are operating with an increase in power consumption. The decoding signal CABmZ output from the predecoder 18 is connected to a large number of column line decoders 10a, and thus is great in wiring length and high in load capacity. Accordingly, the operation of the predecoder 18 consumes more power as compared with those of other circuits.

### SUMMARY OF THE INVENTION

An object of the present invention is to reduce power consumption during the operation of the redundancy circuit as compared to the prior art in a semiconductor integrated circuit having memory cells and a redundancy circuit for relieving the memory cells.

According to one of the aspects of the semiconductor integrated circuit in the present invention, the semiconductor integrated circuit has memory cell blocks, a first decoder, and a second decoder. Each of the memory cell blocks has a plurality of memory cell rows where memory cells are arranged and a redundancy memory cell row for relieving a defect in the memory cell rows. The first decoder selects any of the memory cell blocks. The second decoder selects any of the memory cell rows in the memory cell block. The operation of the second decoder not in use for decoding in the redundancy memory cell row, is suspended when the redundancy memory cell row operates. The absence of unnecessary circuit operation allows a reduction in power consumption at the time of operating the redundancy memory cell row.

According to another aspect of the semiconductor integrated circuit in the present invention, the semiconductor integrated circuit has an address latching circuit for accepting an address signal and supplying the accepted address signal to the second decoder. The address latching circuit suspends the receiving operation of the address signal when the redundancy memory cell row operates, so as to continue to output the address signal previously accepted to the second decoder. Therefore, decoding signals output from the second decoder will not vary in level at the time of operating of the redundancy memory cell row. This makes it possible to reduce unnecessary power consumption of the second decoder.

According to one of the aspects of the semiconductor integrated circuit in the present invention, the semiconductor integrated circuit has a plurality of memory banks each having the plurality of memory cell blocks, the first decoder, and the second decoder. Even in the semiconductor integrated circuit with the plurality of memory banks, the reduction in power consumption can be made when the redundancy memory cell rows operate.

According to another aspect of the semiconductor integrated circuit in the present invention, each of the memory banks has an address latching circuit for accepting an address signal and supplying the accepted address signal to the second decoder. On each of the memory banks, the address latching circuit suspends the receiving operation of the address signal at the time of operating the redundancy memory cell row, so as to keep outputting the address signal previously accepted to the second decoder. Therefore, decoding signals output from the second decoders will not vary in level when the redundancy memory cell rows operate. This makes it possible to reduce unnecessary power consumption of the second decoders.

According to another aspect of the semiconductor integrated circuit in the present invention, the memory cells in the memory cell rows are connected to an identical word line. The first and second decoders decode a row address signal for selecting the word line. That is, the redundancy memory cell row is used to relieve the word line. This allows a reduction in power consumption at the time of relieving the word line.

According to another aspect of the semiconductor integrated circuit in the present invention, the memory cells in the memory cell rows are connected to an identical bit line, and the first and second decoders decode a column address signal for selecting the bit line. That is, the redundancy memory cell row is used to relieve the bit line (or a column line). This allows a reduction in power consumption at the time of relieving the bit line (or a column line).

According to another aspect of the semiconductor integrated circuit in the present invention, the row address signal and the column address signal are concurrently supplied from the exterior. That is, even in the address non-multiplex type semiconductor integrated circuit, the reduction in power consumption can be made when the redundancy memory cell row operates. Moreover, the presence or absence of a bit-line (or column-line) relief can be judged at an earlier time of an operating cycle.

### BRIEF DESCRIPTION OF THE DRAWINGS

The nature, principle, and utility of the invention will become more apparent from the following detailed description when read in conjunction with the accompanying drawings in which like parts are designated by identical reference numbers, in which:

FIG. 1 is a block diagram showing a memory core unit in a DRAM having conventional redundancy circuits.

FIG. 2 is a block diagram showing a conventional memory cell block and its periphery.

FIG. 3 is a block diagram showing the address decoders and redundancy circuits for selecting conventional column line decoders.

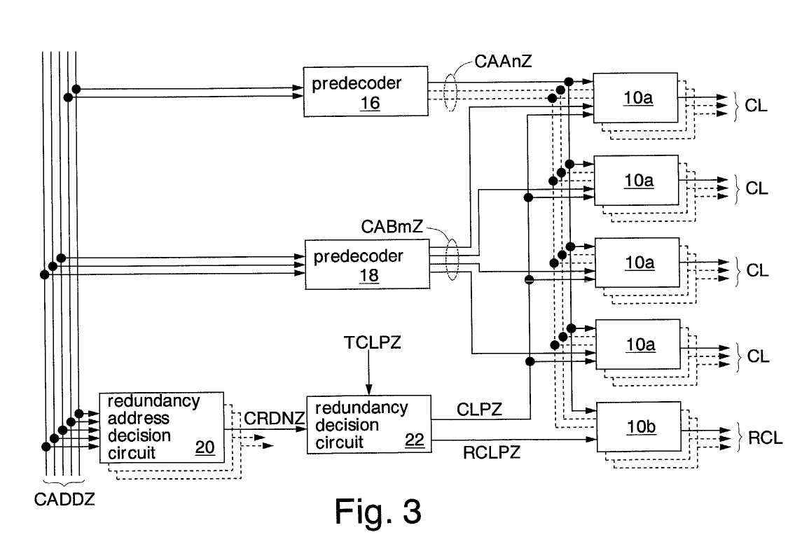

FIG. 4 is a timing chart showing the operation of the circuits shown in FIG. 3.

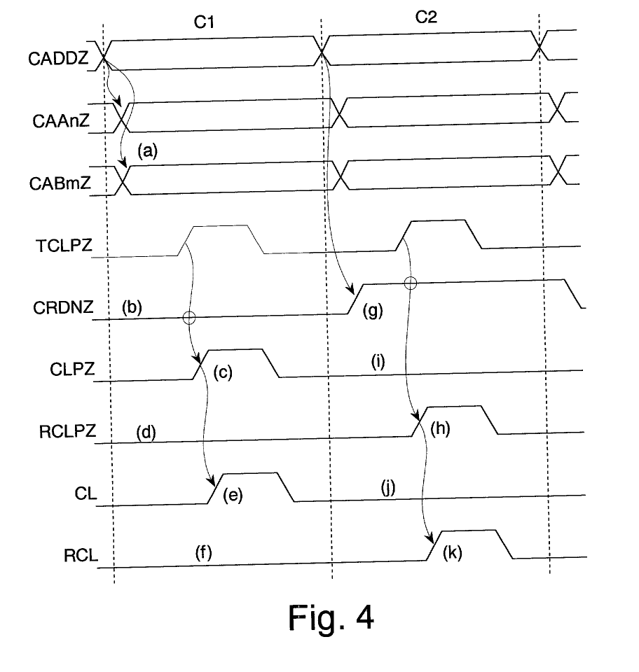

FIG. 5 is a block diagram showing a first embodiment of the semiconductor integrated circuit in the present invention.

FIG. 6 is a block diagram showing circuits related to a column address.

FIG. 7 is a circuit diagram showing the details of an address latching circuit.

FIG. 8 is a timing chart showing the operation of the circuits shown in FIG. 6.

FIG. 9 is a block diagram showing a second embodiment of the semiconductor integrated circuit in the present invention.

FIG. 10 is a block diagram showing circuits related to a column address.

FIG. 11 is a timing chart showing the operation of the circuits shown in FIG. 10.

FIG. 12 is a circuit diagram showing another example of the address latching circuit.

### DESCRIPTION OF THE PREFERRED EMBODIMENTS

Hereinafter, the embodiments of the present invention will be described with reference to the drawings.

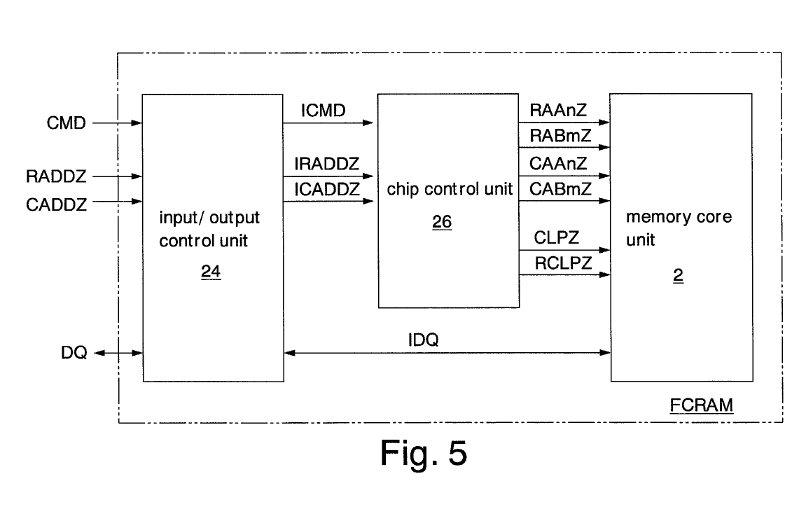

FIG. 5 shows a first embodiment of the semiconductor integrated circuit in the present invention. The same circuits and signals as those described in the conventional art will be designated by identical reference numbers, and detailed description thereof will be omitted.

This semiconductor integrated circuit is formed as an FCRAM (Fast Cycle RAM) on a silicon substrate by using CMOS processes. The general outlines of FCRAMs have been published in NIKKEI ELECTRONICS 1998.6.15 (No. 718), Nikkei business publications.

The FCRAM has an input/output control unit 24, a chip control unit 26, and a memory core unit 2. The input/output control unit 24, the chip control unit 26, and the principal control circuit of the memory core unit 2 are formed of CMOS circuits.

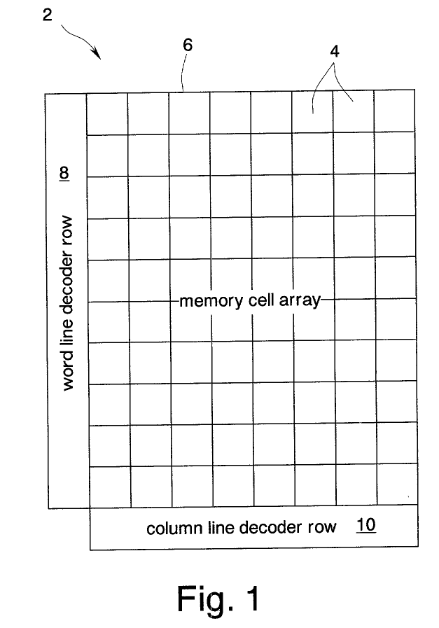

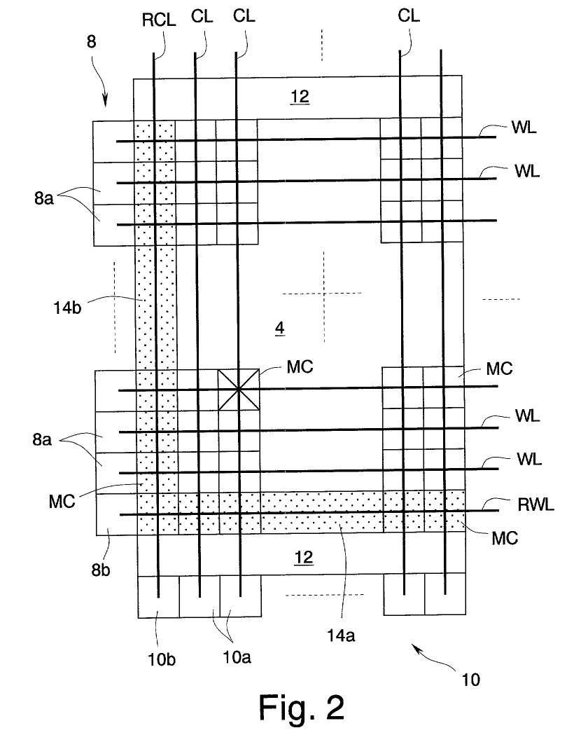

The input/output control unit 24 receives a command signal CMD for setting the operating state of the chip, a row address signal RADDZ, and a column address signal CADDZ from the exterior, and outputs the received signals to the chip control unit 26 as an internal command signal ICMD, an internal row address signal IRADDZ, and an internal column address signal ICADDZ, respectively. The input/output control unit 24 inputs and outputs an input/output data signal DQ from/to the exterior, and inputs and outputs an internal input/output data signal IDQ from/to the memory core unit 2. The chip control unit 26 receives the internal command signal ICMD, the internal row address signal IRADDZ, and the internal column address signal ICADDZ. The chip control unit 26 outputs decoding signals RAAnZ, RABmZ corresponding to a row address, decoding signals CAAnZ, CABmZ corresponding to a column address, and timing signals CLPZ, RCLPZ to the memory core unit 2. The signals shown in FIG. 5 are respectively composed of a plurality of signals. The memory core unit 2 is identical to the conventional circuit (FIG. 1), having a memory cell array 6 in which memory cell blocks 4 are arranged vertically and horizontally. As in FIG. 2, the memory cell blocks 4 have a plurality of memory cell rows including memory cells MC arranged in one directions, and redundancy memory cell rows 14a and 14b for relieving a defect in the memory cell rows. Incidentally, this FCRAM has address terminals for both the row address signal RADDZ and the column address signal CADDZ. The row address signal RADDZ and the column address signal CADDZ are supplied from the exterior at the same time. This FCRAM is an address non-multiplex type memory.

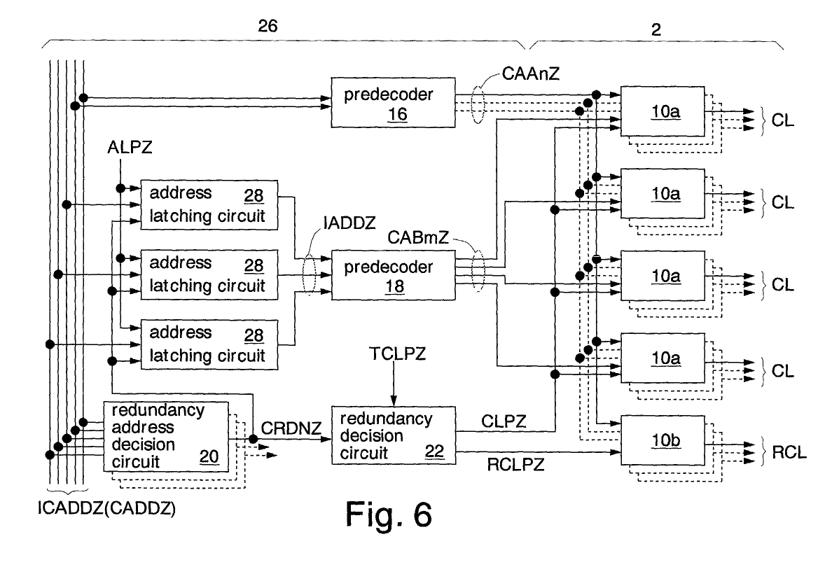

FIG. 6 shows the circuits related to a column address in the chip control unit 26 and the memory core unit 2.

In this embodiment, the predecoder 18 for decoding a lower address receives an internal address signal IADDZ which has been accepted into address latching circuits 28. The address latching circuits 28 are circuits for accepting the internal address signal ICADDZ in synchronization with an address latching signal ALPZ when a redundancy signal CRDNZ is at low level. The circuit configuration excepting the address latching circuits 28 is the same as the conventional one. The predecoder 16 corresponds to the first decoder, and the predecoder 18 the second decoder.

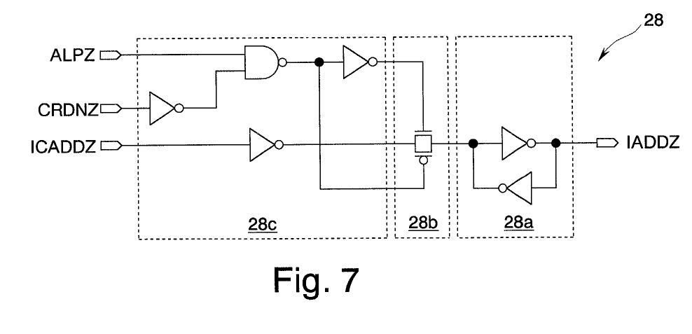

FIG. 7 shows the details of the address latching circuits 28.

The address latching circuit 28 has: a latch 28a having two inverters connected to each other at their inputs and outputs; a CMOS transmission gate 28b for transmitting the internal address signal ICADDZ to the latch 28a; and a control circuit 28c for controlling the CMOS transmission gate 28b. The control circuit 28c turns on the CMOS transmission gate 28b when it receives the address latching signal ALPZ of high level and the redundancy signal CRDNZ of low level.

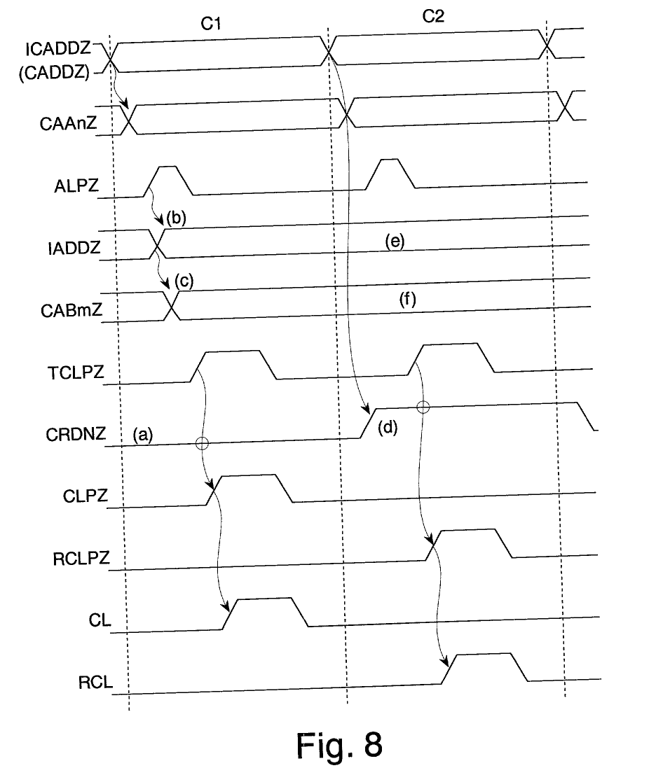

FIG. 8 shows the operations of the circuits shown in FIG. 6. Here, description will be omitted of conventional operations.

In the first operating cycle C1, the redundancy address decision circuits 20 receive the internal address signal ICADDZ, and output the redundancy signal CRDNZ of low level (FIG. 8(a)). That is, the column address signal CADDZ supplied at the operating cycle C1 is not an address corresponding to a defective memory cell MC. The address latching signal ALPZ is turned to high level for a predetermined period. The address latching circuits 28 receive the redundancy signal CRDNZ of low level, accept the internal address signal ICADDZ in synchronization with the address latching signal ALPZ, and output the accepted signal as the internal address signal IADDZ (FIG. 8(b)). The predecoder 18 decodes the internal address signal IADDZ, and outputs the decoded signal as the decoding signal CABmZ (FIG. 8(c)). The timings of the decoding signal CAAnZ, the timing signals TCLPZ, CLPZ, and RCLPZ, the column lines CL, and the redundancy column line RCL are the same as those of the conventional. Then, a memory cell row corresponding to a predetermined column line CL is selected for a read or write operation.

Next, in the operating cycle C2, the redundancy address decision circuits 20 receive the internal address signal ICADDZ to output the redundancy signal CRDNZ of high level (FIG. 8(d)). That is, the column address signal CADDZ supplied at the operating cycle C2 is an address corresponding to a defective memory cell MC. Since this column address signal CADDZ is supplied from the exterior simultaneously with the row address signal RADDZ, a decision on a relief can be made immediately after the start of the operating cycle C2. The address latching circuits 28 are inactivated under the redundancy signal CRDNZ of high level. Therefore, the latches 28a (FIG. 7) in the address latching circuits 28 keep on outputting the internal address signal IADDZ that has been accepted in the operating cycle cl (FIG. 8(e)). As a result, the predecoder 18 continues to receive the same internal address signal IADDZ as that of the operating cycle C1, and thus continues to output the same decoding signal CABmZ (FIG. 8(f)). The principal control circuits including the predecoder 18 and the column line decoders 10a and 10b are formed of CMOS circuits. Accordingly, the predecoder 18 consumes little power.

The timings of the decoding signal CAAnZ, the timing signals TCLPZ, CLPZ, and RCLPZ, the column lines CL, and the redundancy column line RCL are the same as those of the conventional. Then, a redundancy memory cell row corresponding to this redundancy column line RCL is selected for a read or write operation.

As described above, in the semiconductor integrated circuit of the present invention, the operation of the predecoder 18 is suspended when a redundancy memory cell row 14b starts operating. Specifically, the address latching circuits 28, during the operation of a redundancy memory cell row 14b, continue to output an address accepted in the previous operating cycle. This allows a reduction in power consumption when the redundancy circuits operate. In this embodiment, the reduction in power consumption can be realized at the time of relieving the bit lines (or the column lines CL).

In addition, since the present invention is applied to an address non-multiplex type FCRAM, the presence or absence of relief of a bit line (or a column line CL) can be determined at an earlier time of an operating cycle.

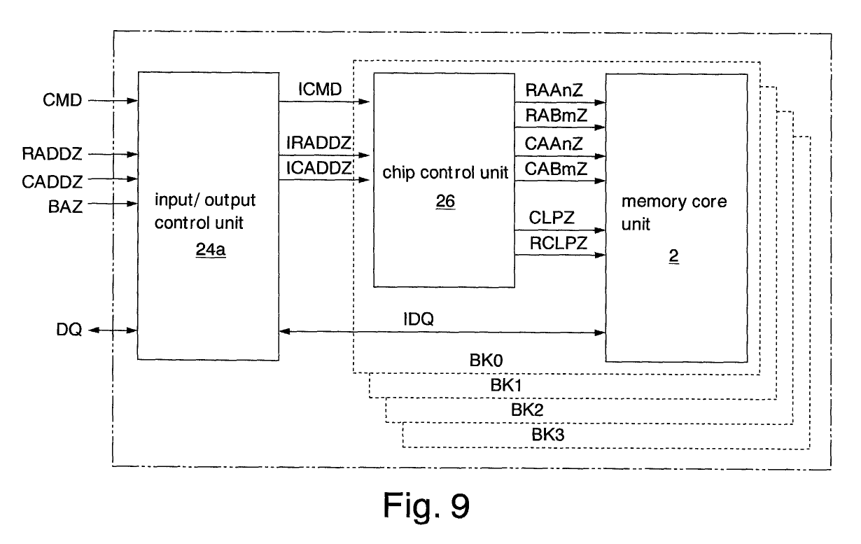

FIG. 9 shows a second embodiment of the semiconductor integrated circuit in the present invention. The same circuits and signals as those described in the conventional art and in the first embodiment will be designated by identical reference numbers, and detailed description thereof will be omitted.

In this embodiment, the FCRAM has four memory banks BK0, BK1, BK2, and BK3. Each of the memory banks BKO-BK3 has a chip control unit 26 and a memory core unit 2. The internal command signal ICMD, the internal row address signal IRADDZ, and the internal column address signal CADDZ are supplied to the chip control units 26 on the respective memory banks BKO-BK3. An input/output control unit 24a receives a bank address signal BAZ for selecting the memory banks BKO-BK3 The other configuration is the same as that of the first embodiment described above.

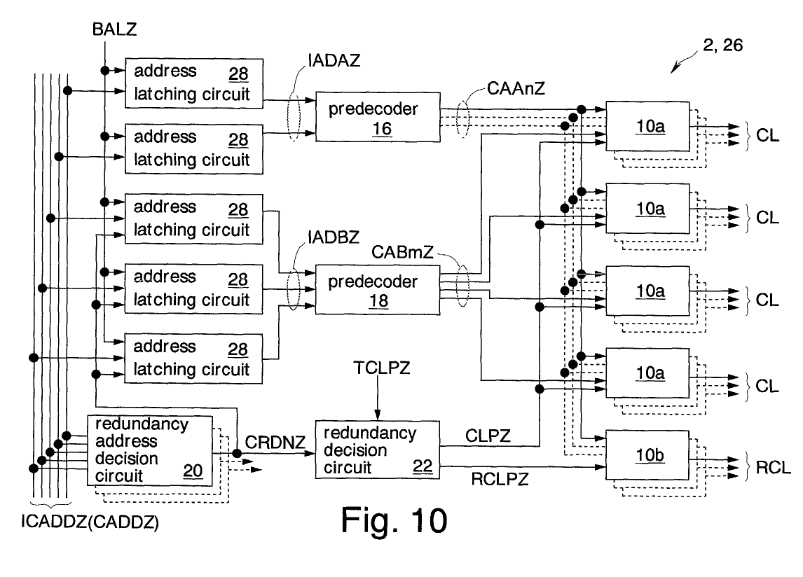

FIG. 10 shows the circuits related to a column address in the chip control units 26 and the memory core units 2 on the memory banks BK0-BK3.

In this embodiment, the predecoder 16 for decoding an upper address receives an internal address signal IADAZ which has been accepted into address latching circuits 28. As in the first embodiment, the predecoder 18 receives an internal address signal IADBZ which has been accepted into address latching circuits 28. The address latching circuits 28 connected to the predecoder18 receive a bank address signal BALZ instead of the address latching signal ALPZ shown in FIG. 6. The circuit configuration excepting the address latching circuits 28 is the same as the conventional one. Incidentally, the address latching circuits 28 are not arranged anew for the sake of the present invention but are configured by utilizing address latching circuits that are conventionally arranged on the memory banks BKO-BK3. Specifically, the address latching circuits 28 are formed by adding the logic of the redundancy signal CRDNZ to the conventional address latching circuits.

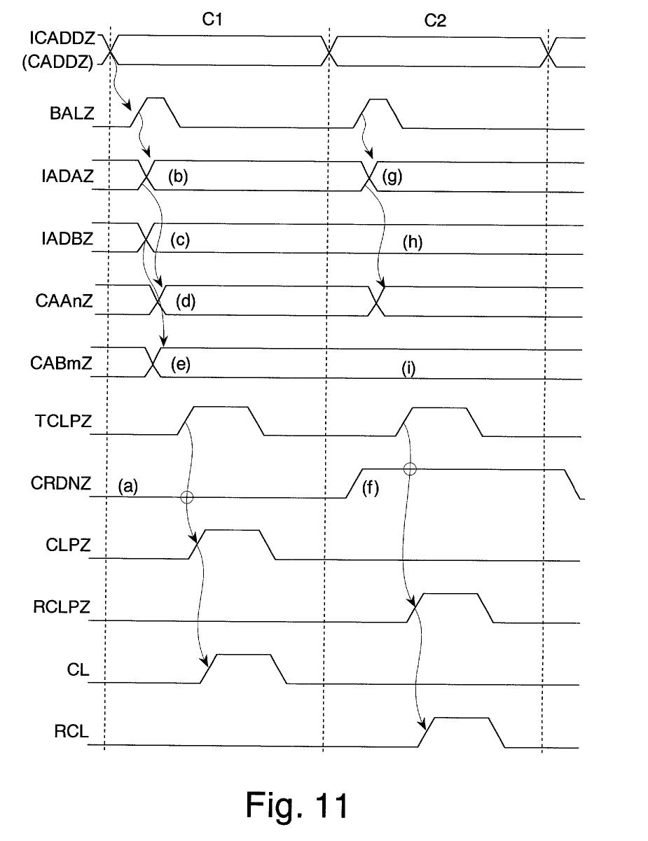

FIG. 11 shows the operations of the circuits shown in FIG. 10. Here, description will be omitted of the same operations as those of the first embodiment.

In the first operating cycle C1, the bank address signal BALZ is turned to high level for a predetermined period. The redundancy address decision circuits 20 receive the internal address signal ICADDZ and output the redundancy signal CRDNZ of low level (FIG. 11(a)). That is, the column address signal CADDZ supplied at the operating cycle C1 is not an address corresponding to a defective memory cell MC. The address latching circuits 28 corresponding to the predecoder 16 accept the internal address signal ICADDZ in synchronization with the bank address signal BALZ, and output the accepted signal as the internal address signal IADAZ (FIG. 11(b)). similarly, the address latching circuits 28 corresponding to the predecoder 18 receive the redundancy signal CRDNZ of low level, accept the internal address signal ICADDZ in synchronization with the bank address signal BALZ, and output the accepted signal as the internal address signal IADBZ (FIG. 11(c)). The predecoder 16 decodes the internal address signal IADAZ, and outputs the decoded signal as the decoding signal CAAnz (FIG. 11(d)). The predecoder 18 decodes the internal address signal IADBZ, and outputs the decoded signal as the decoding signal CABmZ (FIG. 11(e)). The decoding signal CAAnZ, the timing signals TCLPZ, CLPZ, and RCLPZ, the column lines CL, and the redundancy column line RCL have the same timing as the conventional. Then, on the memory bank selected by the bank address signal BALZ, a memory cell row corresponding to a predetermined column line CL is selected for a read or write operation.

Next, in the operating cycle C2, the redundancy address decision circuits 20 receive the internal address signal ICADDZ to output a redundancy signal CRDNZ of high level (FIG. 11(f)). That is, the column address signal CADDZ supplied at the operating cycle C2 is an address corresponding to a defective memory cell MC. The address latching circuits 28 corresponding to the predecoder 16 accept the internal address signal ICADDZ in synchronization with the bank address signal BALZ, and output the accepted signal as the internal address signal IADAZ (FIG. 11(g)). Meanwhile, the address latching circuits 28 corresponding to the predecoder 18 are inactivated under the redundancy signal CRDNZ of high level. On this account, the latches 28a (FIG. 7) in the address latching circuits 28 corresponding to the predecoder 18 keep on outputting the internal address signal IADBZ that has been accepted in the operating cycle C1 (FIG. 11(h)). As a result, the predecoder 18 continues to receive the same internal address signal IADBZ as that of the operating cycle C1, and thus continues to output the same decoding signal CABmZ (FIG. 11(i)). consequently, the predecoder 18 consumes little power.

The timing signals TCLPZ, CLPZ, and RCLPZ, the column lines CL, and the redundancy column line RCL have the same timing as the conventional. Then, on the memory bank selected by the bank address signal BALZ, a redundancy memory cell row corresponding to the redundancy column line RCL is selected for a read or write operation.

As seen from above, this embodiment can also offer the same effects as those obtained from the first embodiment mentioned above. Moreover, according to this embodiment, the unnecessary power consumption by the predecoders 18 can be reduced even in the semiconductor integrated circuit having a plurality of memory banks BK0-BK3. In other words, the reduction in power consumption can be made when the redundancy memory cell rows 14b OPERATE.

Moreover, the conventional address latching circuits 28 arranged on the individual memory banks BK0-BK3 can be utilized.

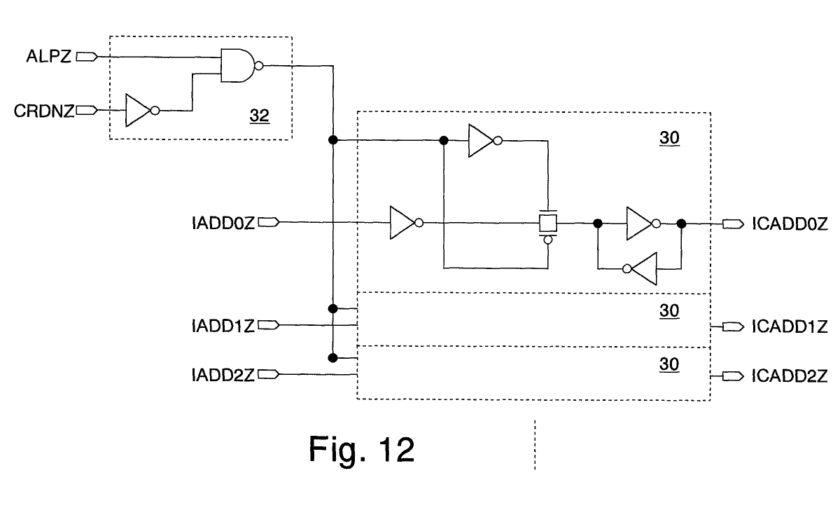

The above-described embodiments have dealt with the cases where the address latching circuits 28 each are provided with a control circuit 28c. However, the present invention is not limited to such embodiments. For example, as shown in FIG. 12, the control circuits may be partly shared to form a control circuit 32 for the purpose of simplifying circuits of the address latching circuits 30. In this case, the address latching circuits can be reduced in layout size.

The above-described embodiments have dealt with the cases where a column line CL is relieved while the operation of the predecoder corresponding to the column address is suspended for a reduction in power consumption. However, the present invention is not limited to such embodiments. For example, a word line WL may be relieved while the operation of the predecoder corresponding to the row address is suspended in order to reduce power consumption.

The second embodiment described above has dealt with the case where the logic of the redundancy signal CRDNZ is added to the conventional address latching circuits to form the address latching circuits 28. However, the present invention is not limited to such an embodiment. For example, the conventional address latching circuits may be used as they are, along with a newly provided control circuit (latching circuit) for controlling the internal address signal ICADDZ to be supplied to these address latching circuits.

The invention is not limited to the above embodiments and various modifications may be made without departing from the spirit and the scope of the invention. Any improvement may be made in part or all of the components.

What is claimed is:

1. A semiconductor integrated circuit comprising:
a plurality of memory cell blocks each having a plurality of memory cell rows wherein memory cells are arranged and a redundancy memory cell row for relieving a defect in the memory cell rows;
a first decoder for selecting any of said memory cell blocks; and
a second decoder for selecting any of said memory cell rows in said memory cell block, wherein
an operation of said second decoder is suspended when said redundancy memory cell row operates.

2. The semiconductor integrated circuit according to claim 1, comprising an address latching circuit for accepting an address signal and supplying said accepted address signal to said second decoder, wherein said address latching circuit suspends its receiving operation when said redundancy memory cell row operates, so as to keep outputting said address signal previously accepted to said second decoder.

3. The semiconductor integrated circuit according to claim 1, comprising a plurality of memory banks each having said plurality of memory cell blocks, said first decoder, and said second decoder.

4. The semiconductor integrated circuit according to claim 3, wherein:
each of said memory banks comprises an address latching circuit for accepting an address signal and supplying said accepted address signal to, said second decoder; and
on each of said memory banks, said address latching circuit suspends its receiving operation when said redundancy memory cell row operates, so as to keep outputting said address signal previously accepted to said second decoder.

5. The semiconductor integrated circuit according to claim 1, wherein:
said memory cells in each of said memory cell rows are connected to an identical word line; and
said first and second decoders decode a row address signal.

6. The semiconductor integrated circuit according to claim 1, wherein:
said memory cells in each of said memory cell rows are connected to an identical bit line; and
said first and second decoders decode a column address signal

7. The semiconductor integrated circuit according to claim 6, wherein said column address signal is supplied from exterior simultaneously with a row address signal.
